(19) United States
(12) Patent Application Publication
(10) Pub. No.: US 2009/0122853 A1
(43) Pub. Date: May 14, 2009

(54) CHANNEL TRACKING METHODS FOR SUBSPACE EQUALIZERS

(75) Inventor: Fernando Lopez de Victoria, San Carlos, CA (US)

Correspondence Address: ORRICK, HERRINGTON & SUTCLIFFE, LLP;IP PROSECUTION DEPARTMENT, 4 PARK PLAZA, SUITE 1600, IRVINE, CA, 92614-2558, US

(73) Assignee: Acorn Technologies, Inc.

(21) Appl. No.: 11/938,379

(22) Filed: Nov. 12, 2007

(51) Int. Cl. H03H 7/30

(52) U.S. Cl. 375/232

(57) ABSTRACT

A receiver includes a subspace filter having first and second basis filters, with the first basis filter module generating a weighted average channel estimate. The receiver collects a plurality of channel estimates over an interval and combines the plurality of channel estimates using a weighting factor and summing to generate the weighted average channel estimate. The receiver generates a weighting factor for each of the plurality of channel estimates over the interval the weighting factors vary as a function of the relative velocity of the receiver so that the estimates closest in time to the current estimate are weighted more heavily than estimates further spaced in time from the current estimate.

### BACKGROUND

1. Field of the Invention

The present invention relates to communication systems and, in particular, to wireless receivers that use channel estimation, and especially to wireless receivers that use channel estimation for a channel that varies in time.

2. Description of the Related Art

In many wireless communication systems, the receiver generates a filter to compensate for channel distortions. A receiver filter that functions to remove channel distortions, such as multipath or some form of interference, is termed an equalizer. The convolution of the receiver's filter and the channel's impulse responses ideally results in a single delayed impulse. In multi-carrier modulated systems (e.g., orthogonal frequency-division multiplexed or OFDM), the single impulse constraint is relaxed to allow multiple impulses that span a maximum delay spread, while maintaining zero inter-symbol interference (ISI). This latter filter type is termed a channel shortening filter (CSF). An equalizer is a special case of the channel shortening filter. Design computations for different types of equalizers vary significantly.

Conventional receivers incorporate various equalizer and channel shortening filter design techniques and mechanisms to adapt the equalizer for mobile systems. Predominant among these design techniques is a least-squares criterion, or cost function, that seeks to minimize the filter's output error and consequently seeks to improve the transmitted symbol estimates. Equalizer adaptation usually uses the well known least mean squares (LMS) or recursive least squares (RLS) strategies, which determine estimation errors and use those errors to obtain new filter designs intended to further reduce errors.

This discussion relates to a class of equalizers and channel shortening filters that can be termed subspace equalizers (SEQs) or subspace channel shortening filters (SCSFs). The term subspace filters (SFs) will be used in the following discussion to refer to subspace equalizers and subspace channel shortening filters collectively. Subspace filter design strategies seek to calculate the subspace filter's coefficients as the sum of a small number of filters. The optimum receive filter is approximated by the subspace filter as a weighted sum, or linear combination, of these filters. These other filters are generally called basis filters. There are many different methods to determine these subspace filters using computations that search for eigenvalues and eigenvectors. The textbook, Matrix Computations (Gene H. Golub and Charles F. Van Loan, John Hopkins Press, 3^{rd} Edition, 1996), calls the three more prominent methods for determining these subspace filters the Arnoldi, Lanczos and conjugate gradient methods.

The optimum linear receive filter that minimizes the mean square error is the Wiener filter. Calculation of the Wiener filter, shown in FIG. 1, requires an estimate of the channel and the inversion of the filter input's auto-covariance matrix. Direct calculation of the Wiener filter, called a “direct method,” may not be feasible for time-varying channels and so approximation techniques such as the least mean squares (LMS) method are used to reduce the complexity of obtaining a filter design.

The least mean squares method for filter adaptation does not require computation of the auto-covariance matrix, its inverse nor the channel estimate. FIG. 2 shows the filter and adaptation method used in least mean squares and other similar error-feedback filter adaptation methods such as recursive least squares (RLS). Although implementation complexity is at a minimum with least mean squares, the error feedback input impedes fast channel tracking and limits the accuracy of the filter solution.

Alternatively, many conventional implementations of the Lanczos, Arnoldi and conjugate gradient methods are initialized with the auto-covariance matrix and channel estimate to compute the Wiener filter approximation, as shown in FIG. 3. The advantage of the subspace filter approximation to the Wiener filter is the use of the estimated auto-covariance matrix rather than the far more difficult to obtain inverse of the auto-covariance matrix used in the direct method Wiener filter calculation (FIG. 1). The term “filter design” is used here and throughout the below discussion to refer to the determination of the filter coefficients and other characteristics of the filter. In this sense, filter design is often performed by operating receivers only once for a fixed channel, or at an update rate to track time-varying channels.

To compute the Wiener filter as shown in FIG. 1, the direct method uses the received (input) signal y(k) 101 to estimate 110 its auto-covariance matrix R_{y} 111, and the direct method uses a reference signal d(k) 105 to compute the channel estimate vector p 125. In the next step, the direct method Wiener filter computation calculates the inverse inv(R_{y}) 131 of R_{y} 111. Matrix multiplication 150 computes w=inv(R_{y})p and produces the Wiener filter receiver coefficients. The resulting Wiener filter w 157 is used to filter the related input signal y(k) 101 to produce the filter output x(k).

A typical implementation of the least mean squares method is shown in FIG. 2. Receiver filter (RCVFILT) F(k) 210 filters an input signal y(k) 201. To calculate the next set of filter coefficients at iteration (k+1), the process generates an error between the filter output x(k) 203 and a reference signal d(k) 205. The least mean squares module 230 calculates the filter to be used to filter the next input sample y(k+1) in proportion to the error value generated by the error module 220. This error-feedback filter adaptation method updates the actual filter at a predetermined rate and uses the computed actual filter to filter the corresponding input signal.

Ordinarily, subspace filters take a different approach to designing the receive filter f_{L} 367 shown in FIG. 3. The chosen subspace filter computation method starts with an auto-covariance matrix R_{y} 311 and the channel estimate p 325, as was the case for determining the direct method Wiener filter of FIG. 1, to compute D basis filters. FIG. 3 shows a subspace filter design method that uses D=3 basis filters, and those skilled in the art can extend this illustration to larger values of D. A basis filter computation module 340 applies a method such as those specified by Lanczos or Arnoldi to calculate a new basis filter. These basis filter computation modules are repeated for each additional basis filter needed. The number (D) of basis filters depends on the application for the subspace filter and is usually determined empirically. Each basis filter computation module has two principal outputs, shown in FIG. 3 as f₂ 347 and m₂ 349. The f₂ 347 is the basis filter for that module and m₂ 349 is a collection of scalars, organized as a vector, with computed measures as dictated by the chosen Lanczos or Arnoldi method. Some of the various implementations of the Lanczos or Arnoldi methods may require the basis filter computation modules to use all basis filters that are previous to a currently computed module. The initial values that are inputs to the first basis filter computation module 340 are a special simplified case. The coordinate computation module 360 uses all of the computed basis filters, the measures mᵢ, the auto-covariance matrix and the channel estimate, to compute the weighting scalars that combine the basis filters fᵢ in the coordinate computation module 360. Then, the coordinate computation module 360 uses the coordinates for each basis filter to compute the subspace filter f_{L} 367.

The implementation of a subspace filter in a mobile environment cannot estimate the true auto-covariance matrix R_{y} 311 and so an estimate is computed over a predetermined input signal time interval. This process uses a block of input samples [y(k) to y(k+T)] 301 and a reference signal [d(k) to d(k+T)] 305 to compute the auto-covariance matrix and the channel estimate. The averaging over this period produces the subspace filter, which is used to filter the input signal over the specified period of time and to produce the estimated transmitted signal [x(k) to x(k+T)] 303.

Three different Wiener filter estimation methods are illustrated in FIGS. 1-3. The direct method Wiener filter (FIG. 1) requires the computation of a matrix inverse, while the least mean squares method (FIG. 2) adapts the Wiener filter estimate with an error-feedback filter adaptation method. The direct method Wiener filter can be termed a sample matrix-inverse method, and the error-feedback filter adaptation a sample-filtered error-feedback method, since it uses the sampled input signal. The subspace filter incorporating the Lanczos or Arnoldi method shown in FIG. 3 can be termed a sample-matrix decomposition method, since it uses the sampled input signal to compute the auto-covariance matrix and channel estimates.

U.S. Pat. No. 7,120,657 to Ricks and Goldstein, entitled “System and Method for Adaptive Filtering,” and U.S. Pat. No. 7,181,085 to Despain, entitled “Adaptive Multistage Wiener Filter” (“Despain 1”) offer a formulation of the Arnoldi subspace method as a sample-filtered decomposition. That is, these methods avoid the computation of an auto-covariance matrix and instead filter the input signal to compute the basis filters and their corresponding coordinates in a prescribed manner. These two sample-filtered decomposition subspace filter methods produce the same Arnoldi sample-matrix decomposition filter f_{L} 367 in FIG. 3.

Other Wiener filter determination techniques average channel estimate observations as part of estimating the filter through subspace filter methods. U.S. patent application Ser. No. 10/894,913 to Despain, filed Jul. 19, 2004, entitled “Use of Adaptive Filter in CDMA Wireless Systems Employing Pilot Signals” (“Despain 2”) describes a method to average over a sliding window on the input signal for CDMA signals. In mobility applications, the channel changes quickly with time, and there is a particularly advantageous time period over which to average a small number of channel estimates. The average may be computed as equally weighted channel estimates over a finite window, which slides for the next estimate with a predetermined amount of overlap.

### SUMMARY OF THE PREFERRED EMBODIMENTS

According to an aspect of the present invention, a receiver comprising a subspace filter for filtering data includes a first basis filter. The first basis filter generates a plurality of channel estimates from received information including a current channel estimate for a current time interval. The current channel estimate is determined as a weighted average of the plurality of channel estimates using a weighting function. The weighting function is a measure of similarity between channel estimates and varying as a function of relative receiver velocity so that the weighting function has a larger magnitude for channel estimates closer in time to the current time and has a smaller magnitude for channel estimates further in time from the current time. The first basis filter outputs a first basis filter estimate responsive to the current channel estimate and the received information. The receiver includes a second basis filter, the second basis filter receiving the first basis filter estimate and generating a second basis filter estimate responsive to the first basis filter estimate.

According to an aspect of the present invention, a receiver comprising a subspace filter for filtering data includes a first basis filter. The first basis filter generates a plurality of channel estimates from received information including a current channel estimate for a current time interval. The current channel estimate is determined as a weighted average of the plurality of channel estimates using a weighting function. The first basis filter outputs a first basis filter estimate responsive to the current channel estimate and the received information. The first basis filter generates a first similarity measure between the first basis filter and a channel estimate once per symbol, the first similarity measure used to generate a correction to the first basis filter estimate. A second basis filter receives the first basis filter estimate and generates a second basis filter estimate responsive to the first basis filter estimate.

Another aspect of the invention provides a receiver comprising a subspace filter for filtering data. The receiver comprises a plurality of basis filters including a first basis filter and a second basis filter; and a basis filter combination module that combines at least selected outputs of the plurality of basis filters to determine a subspace filter. The first basis filter generates a plurality of channel estimates from received information including a current channel estimate for a current time interval. The current channel estimate is determined as a weighted average of the plurality of channel estimates using a weighting function. The weighting function is a measure of similarity between channel estimates and varying as a function of relative receiver velocity so that the weighting function has a larger magnitude for channel estimates closer in time to the current time and has a smaller magnitude for channel estimates further in time from the current time. The first basis filter outputs a first basis filter estimate responsive to the current channel estimate and the received information and the second basis filter receives the first basis filter estimate and generates a second basis filter estimate responsive to the first basis filter estimate. The first basis filter outputs the weighting function to at least the second basis filter.

### BRIEF DESCRIPTION OF THE DRAWINGS

Aspects of the present invention are illustrated in the attached drawings and can be better understood by reference to those drawings in conjunction with the detailed description. The attached drawings form a part of the disclosure.

FIG. 1 illustrates a functional block diagram of a direct method of determining a Wiener filter.

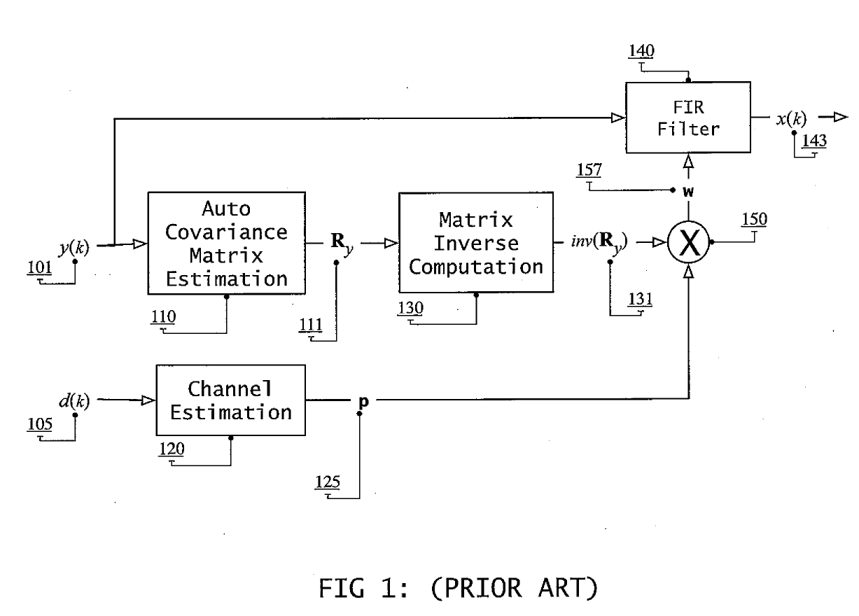

FIG. 2 illustrates a functional block diagram for an error-feedback filter adaptation method for estimating a Wiener filter, such as in a least mean squares method of estimating the Wiener filter.

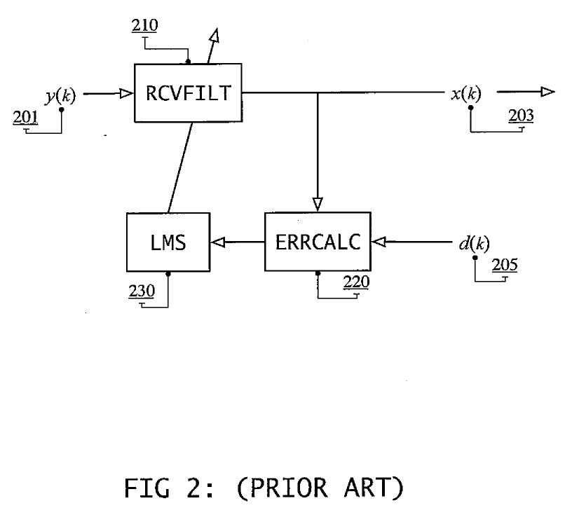

FIG. 3 illustrates a functional block diagram for a sample-matrix decomposition method to obtain a subspace filter approximation to the Wiener filter.

FIG. 4 illustrates a functional block diagram of a receiver that uses a sample-filtered decomposition method to obtain a subspace filter. The output is computed directly from each basis filter's filtered signal output.

FIG. 5 illustrates a functional block diagram of a first basis filter module that may be used as 410 in FIG. 4. The illustrated first basis filter module uses a sample-filtered decomposition method to obtain a subspace filter.

FIG. 6 illustrates a functional block diagram for a receiver that uses a sample-filtered decomposition method to obtain a subspace filter. The FIG. 6 filter is particularly suited to mobile receiver applications.

FIG. 7 shows a preferred implementation of a basis filter module, which might be used in the filter circuit of FIG. 6, that includes an integrated weight calculation module to produce a weighted average over a set of channel estimates.

FIG. 8 shows a preferred implementation of a weight calculation module that might be used in the filter circuit of FIG. 7.

FIG. 9 illustrates a subspace filter and subspace filter design using reduced complexity determination of basis filter coordinates.

FIG. 10 illustrates a hardware-efficient implementation of the basis filter coordinates calculations according to certain preferred embodiments of the invention.

### DETAILED DESCRIPTION OF THE PREFERRED EMBODIMENTS

Preferred embodiments of the present invention include subspace filters and methods for generating subspace filters that combine a set of channel estimates, preferably calculated over one received symbol period, to improve the channel estimate that seeds the computation of a subspace basis filter. Most preferably the channel estimates are combined according to a set of weights for each symbols channel estimate where the weights are sensitive to a mobile receiver's Doppler rate or rates.

Other preferred embodiments of the present invention include subspace filters and methods for generating subspace filters that determine subspace basis filter coordinates with reduced complexity, lower computational latency and lower power consumption. These reduced complexity techniques and implementations may be used independently of the channel estimate combining techniques and implementations described above, but particularly preferred embodiments use them in combination.

This discussion relates in certain aspects to implementations of the Arnoldi or Lanczos methods to design subspace filters with lower complexity that accommodate at least some of the limitations typical of mobile receivers. Preferred implementations provide improved performance in time-varying channel conditions. While mobile receivers are a particularly preferred implementation, aspects of the present invention can be implemented to improve the performance or reliability of stationary receivers. This discussion illustrates preferred embodiments in the context of mobile receivers with the understanding that details of other embodiments will be apparent to those of ordinary skill.

In mobile communication systems a subspace filter may encounter the problem that speed or symbol durations conflict with the optimum or preferred choice of the data block size T+1 for determining the subspace filter. That is, the symbol duration may be much smaller than T+1, and any averaging over a period T+1 with randomized data may cause the mean of all observations to approach zero due to symbol transitions. Independent of symbol modulation, if the speed of a mobile receiver causes the channel to change significantly over a period of data T+1, then the achievable performance is compromised.

Certain preferred implementations may use multiple channel estimates over short intervals to obtain a set of weighting coefficients used in linearly combining channel estimates prior to processing by a sample-matrix method to design a subspace filter. This weighted-average strategy effectively determines the best window length to perform a channel estimate average in the presence of channel variations due to a mobile receiver's relative motion or velocity.

Modern digital communication systems, including typical wireless communications systems, transmit raw information bits (ones and zeros) in varying sophisticated approaches. To increase capacity, communication systems usually combine a given number of bits to form a symbol. For example, four bits can be combined and mapped into a specific symbol out of a total of sixteen different symbols. Therefore, in the period of time that one bit was previously transmitted, a single symbol is transmitted, representing four bits to provide a four-fold increase in transmission capacity. Symbol transmission comes at the expense of a four-fold increase in power required as compared to single bit transmission, but the bandwidth remains the same since the symbol time and bit time durations are equal. The strategies to map a group of bits to a symbol and how that symbol is electrically transmitted over a medium can vary from system-to-system. Nevertheless, all such systems can be said to have a “symbol modulated signal.” Well-known standards detail how the symbol modulated signal is constructed (modulated) and processed (demodulated) at the receiver to extract the information bits.

Increasing the transmission capacity by organizing data into symbols is balanced against increasing the chances of symbol error if the transmit power is kept the same when transmitting data in bits or symbols. Symbol errors in turn can be mapped to a number of bit errors. The number of errors can be exacerbated by the presence of multiple signal replicas. For example, in wireless systems, signal reflections from multiple paths arrive at the receiver at random delays. The increased sensitivity associated with symbol transmission strategies and the varying channel conditions usually require that an adaptive equalizer be incorporated at the receiver.

Modern wireless systems group a prescribed number of symbols into a packet, frame or block. This short duration packet is intended for one, or more, users. Therefore, the receiver preferably calculates the equalizer that minimizes the symbol error rate prior to packet demodulation. Due to the packet's short duration, the wireless system generally includes a training signal that can be inserted at the beginning of the packet, as in certain orthogonal frequency-division multiplexed (OFDM) systems. Other systems provide a training signal that is continued for the duration of the packet, as in certain OFDM and certain CDMA systems. This training signal is a pre-determined symbol-modulated pilot signal. Providing training or pilot signals facilitates fast signal acquisition and demodulation in wireless communication systems.

Pilot signals or pilot subchannels may be present in a transmitted waveform over a short interval at the beginning of a burst transmission or multiplexed with modulated user data. In some systems, the pilot signal is designed to be orthogonal, that is to provide zero or little interference, to other channels through time, code and/or frequency orthogonality. Pilot signals are easily generated at the receiver, since the modulated data is trivial (e.g., all ones) or consists of a predetermined modulated data sequence.

A preferred wireless receiver uses a pilot signal in a preferred manner to estimate the basis vectors in designing a subspace filter. This receiver is particularly useful when the target receive filter performance requires an averaging period T+1 much greater than the signal's symbol period or when there are time varying channel changes during an averaging interval. Such conditions generally require modifications to the conventional subspace filter determination strategies.

Determining a subspace filter according to preferred embodiments preferably includes two steps: (1) designing the basis filters and (2) estimating the basis filter coordinates. Once these two quantities are known, the process for determining the filter can continue to determine the linear combination of the basis filters that produces a desirable subspace filter. A preferred subspace filter implementation preferably averages over multiple symbol periods to obtain the basis filters for symbol-modulated signals over time-varying channels. Another preferred aspect can provide a subspace filter by using an improved calculation of the basis filter coordinates when averaging for symbol modulated signals or time-varying channels.

Estimating any sampled signal parameter in the presence of noise generally proceeds by making at least a minimum number of discreet observations. Usually, simulations are used to determine the span of digitized input samples to be processed to achieve a target estimation mean-square error value. If the span starting with the sample indexed by k is given as T+1 samples, the subspace filter design procedure generally uses all T+1 samples to estimate the basis filters and their corresponding coordinates in determining the subspace filter. The resulting filter then filters all T+1 samples to produce the filter's output signal. This process is repeated with a filter calculation based on the next T+1 samples.

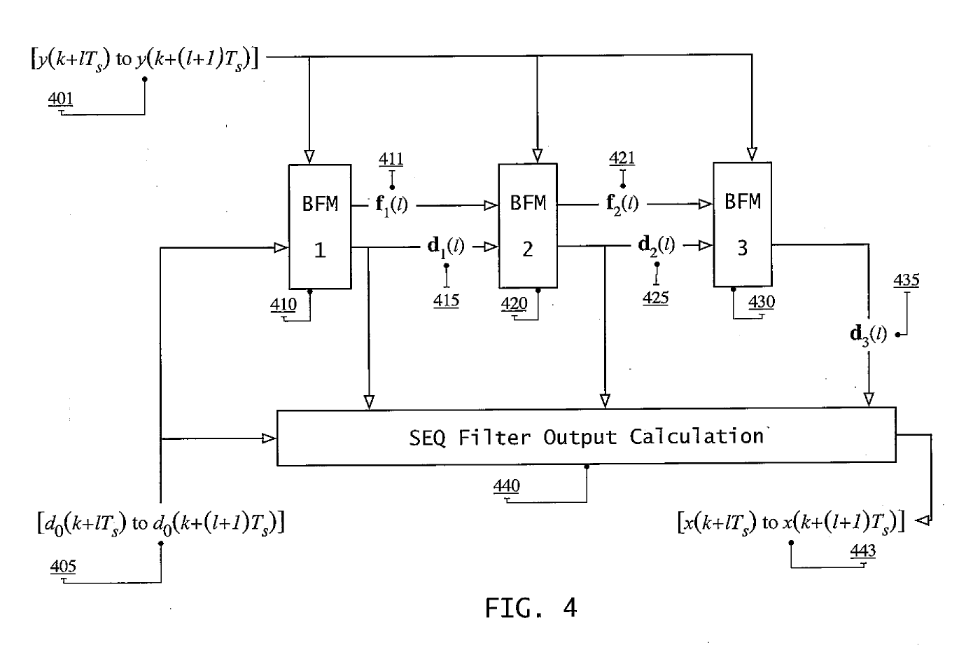

FIG. 4 shows a typical procedure to generate the basis filters for a case of D=3 basis filters, based on the Lanczos method that implements a sample-filtered decomposition. Each basis filter module (such as 420) generates a basis filter (such as f₂(l) 421) from the input data [y(k+lT) to y(k+(l+1)T)] 401 and a reference signal d₁(l) 415 and produces the next reference signal d₂(l) 425 by filtering the input data with f₂(l) 421. Most preferably the procedure begins using a predetermined span of T+1 input samples [y(k+lT) to y(k+(l+1)T)] 401, at some iteration index l, to estimate the channel inside the first basis filter module 410 that serves as the initial estimate for the first basis filter f₁(l) 411. Here the filter coefficients are denoted as a vector, as are all variables with boldface lower-case letters. The first basis filter's f₁(l) 411 calculation is given by the normalized channel estimate (computed inside the first basis filter module 410).

The second basis filter module 420 follows a similar process and set of computations. First, the second basis filter module 420 correlates the input data [y(k+lT) to y(k+(l+1)T)] 401 with the first basis filter module 410 filtered data [d₁(k+lT) to d₁(k+(l+1)T)] 415, represented as the vector d₁(l), over the same segment of T+1 samples. This produces another cross-correlation estimate p₂(l) internally in basis filter module 420 that is normalized to produce the second basis filter output f₂(l) 421, which may be adjusted by subtracting values computed in previous basis filter modules as dictated by the choice of the Lanczos or Arnoldi methods. As is the case in the previous (first) stage, the second basis filter module 420 computes the fitter output [d₂(k+lT) to d₂(k+(l+1)T)], represented as the vector d₂(l) 425, from the same input samples [y(k+lT) toy(k+(l+1)T)] 401, which may be adjusted by subtracting values computed in previous basis filter modules as dictated by the choice of Lanczos or Arnoldi or other methods.

This same procedure outlined for the second basis filter module 420 is repeated for the third basis filter module 430, and is repeated for any subsequent modules until the final module is reached. In the example shown in FIG. 4, there are three basis filter modules. Depending on the input signal's 401 statistical properties, and the specific strategy selected for determining the basis filters, the computations for the basis filters and corresponding outputs may depend on one or more previous basis filters and their corresponding filtered outputs. For example, Arnoldi computations at module index 2≦n≦D would require that all previous basis filters and their respective outputs be inputs to the current basis filter module. Lanczos basis filter module computations generally require the previous two basis filters and corresponding outputs to compute the adjustment values. Implementing such basis filter modules is well understood and readily accomplished by those in this field.

The subspace equalizer filter signal output may be computed as a linear combination of each basis filter output. This is shown as the subspace equalizer filter output calculation module 440. The module calculates the corresponding real, or complex, scalars that weight each filter output signal vector dᵢ(l) (415, 425 and 435). These weighted filter outputs are summed to provide the subspace equalizer filter output 443.

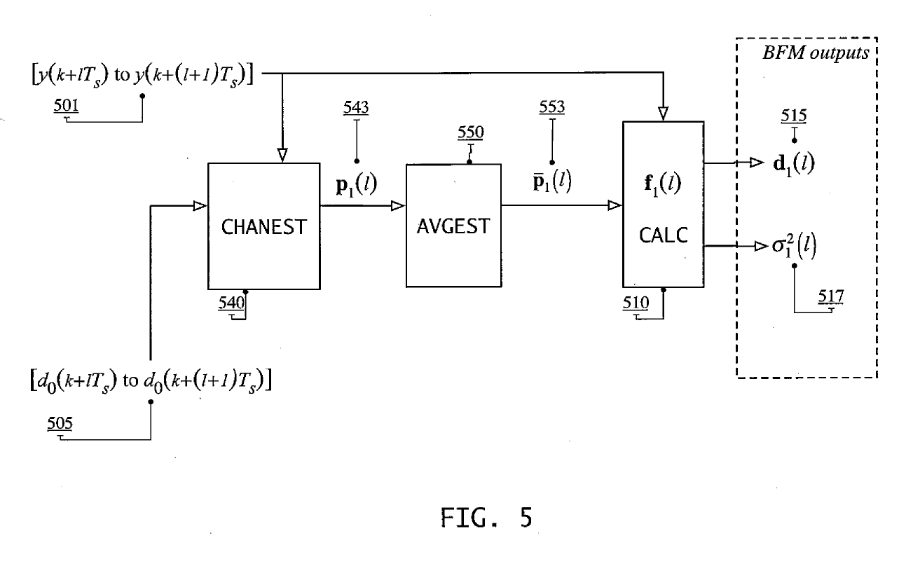

FIG. 5 shows an exemplary implementation of the first basis filter module of FIG. 4. As illustrated, the basis filter module determines an initial channel estimate from the cross-correlation between the reference signal [d₀(k+lT) to d₀(k+(l+1)T)] 505 (such as a locally synthesized version of a pilot signal) and the input signal [y(k+lT) to y(k+(l+1)T)] 501 in the channel estimation module 540. After normalizing the channel estimate p₁(l) 543, the first basis filter module 510 computes a filtered output [d₁(k+lT) to d₁(k+(l+1)T)], represented by the vector dᵢ(l) 515, with the normalized filter in 510 and provides this output 515 to the second basis filter module 420 (in FIG. 4).

These three principal modules in FIG. 5 make up a basis filter module for a typical sample-filtered subspace equalizer (e.g., 410, 420, 430 in FIG. 4) and generate the corresponding signals output by the basis filter module. FIG. 5 shows the indexed signals within the first basis filter module. The channel estimation module 540 preferably implements a cross-correlation that exploits a preferable orthogonal training or pilot signal, as in CDMA and OFDM modulations, to estimate the channel including whatever pulse shaping and multipath might exist in the channel. Subsequent basis filter modules perform cross-correlations that may not be exactly channel impulse response estimates.

A preferred receiver filter preferably implements a cross-correlation between the reference signal 505 and the input signal 501 to estimate the channel in the channel estimation module 540. Various other channel estimation strategies, including increasingly sophisticated computational methods are known, especially for OFDM systems. Those skilled in the art can perform the necessary analysis and tradeoffs to determine how best to perform channel estimation constrained by the computational power available at the receiver.

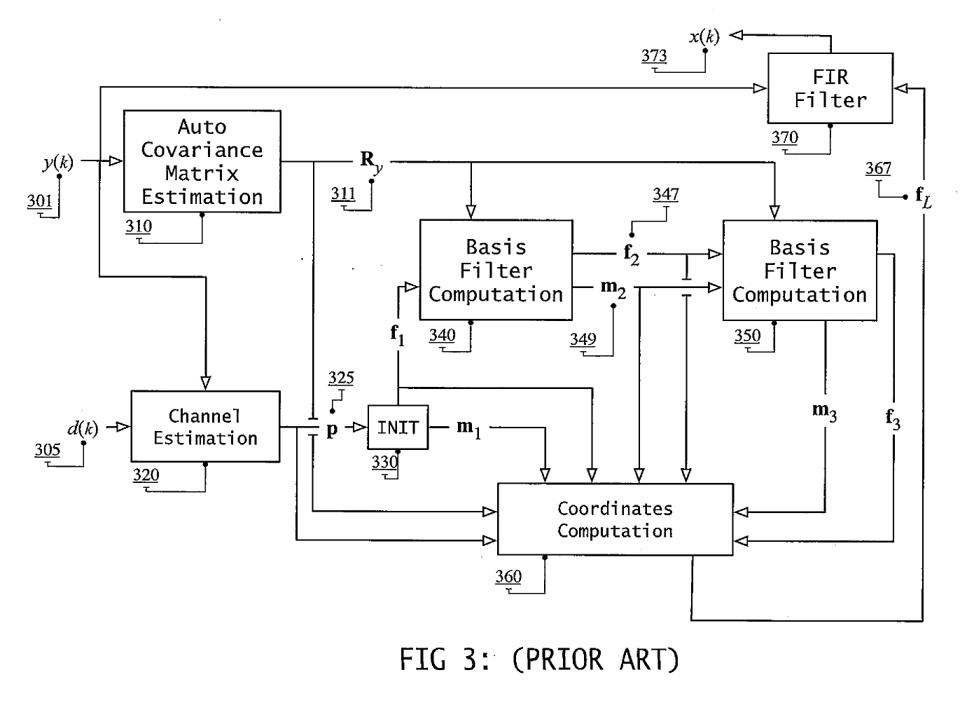

Using a subspace filter to approximate the Wiener filter combines a weighted sum of the D filter estimates, shown in FIG. 4 as the outputs of each of the basis filter modules. Determining the weights for each corresponding basis filter may be performed using the computation of the f_{D}(l) filter. These weights are termed here as coordinates. Hence, the coordinate computation module 440 may take as input each individual basis filter and other measures computed inside the basis filter modules as part of the chosen approach between Lanczos or Arnoldi or other strategy. The coordinate computation 440 is equivalent in function to the module 360 shown in FIG. 3.

Preferred receivers described here are especially well suited to obtain the values for all basis filters fₙ(l) for a time varying channel and when using fewer than T+1 samples, when Tₛ+1 is a comparatively small fraction of T+1; all basis filters are estimated over Tₛ+1 and the basis filters preferably are averaged in an advantageous manner over the particularly preferred T+1 interval. For example, in CDMA2000 systems, a binary-valued symbol has 64 chips to spread and scramble each symbol. To avoid opposite polarity symbols from canceling the channel estimate over the multiple symbol periods in T+1 samples, the basis filter estimate f₁(l) preferably is calculated over one symbol, or 64 chips. Thus, the index l preferably indicates one symbol period. Subsequent basis filter modules preferably perform cross correlations over the same one-symbol interval, also indexed with l. On the other hand, empirical studies show that a time span of many symbols, as in a period of T+1 samples, is preferred to obtain an estimate f₁(l) that has the target estimation mean-square error value. Consequently, certain preferred embodiments may use a time span of an integer number of many symbols.

In the case of orthogonal frequency-division multiplexing (OFDM) systems such as WiFi and WiMax, there are a number of OFDM preamble training symbols and/or carrier frequencies, followed by pilot tones in pre-assigned carrier locations for frequencies during data transmission to provide a reference signal 405 at the receiver. The number of preamble symbols and specific pilot tone locations are standard-dependent. Therefore, the generation of the reference signal 405 varies between standards, and may vary from symbol to symbol. In all cases, the values of the reference signal 405 are always known at the receiver.

A simple and particularly preferred approach to achieve the target channel estimation performance over T+1 input samples is to average the values of p₁(l) over a number of symbols L, where each symbol is spanned by [y(k+lTₛ) to y(k+(l+1)Tₛ)]. Then,

$${\overline{p}}_{1} ( l ) = \frac{1}{L} {\sum }_{i = 0}^{L - 1} {p}_{1} ( l - i ) \qquad ( 1 )$$

where L*(Tₛ+1) is a duration close to the optimum block length T+1, and Tₛ+1 is the number of samples in a modulated symbol. The purpose of this averaging is to achieve an estimation performance over T+1 samples with p̅₁(l) given by Equation (1) that is similar to the estimation performance given by p₁(l) averaged over T+1 unmodulated samples.

Equation (1) represents one of many approaches to averaging a set of channel estimates, or any parameter, and is implemented in the AVGEST 550 module shown on FIG. 5. Two types of averaging can be defined: (A) infinite window and (B) finite window. An infinite window averages from the present value to all previous values. This kind of averaging is impractical, but can be approached with a recursive equation, such as

p̅₁(l)=ap₁(l)+(1−a) p̅₁(l−1) (2)

usually termed an exponentially-decaying weighted averaging. This term arises from the weight, or scaling, of p̅₁(l−i) added to the present value of p̅₁(l). The scaling factor is (1−a)ⁱ⁻¹ and therefore it is viewed as a forgetting factor on prior values. In mobile systems, an averaging method that computes Equation (2) will encounter channel tracking difficulties at high speed due to requirements of higher values for a, which can make the resulting average estimate unstable.

A more general formulation for Equation (1) is to give a scaling factor to each measurement p̅₁(l−i). That gives the formulation

$${\overline{p}}_{1} ( l ) = {\sum }_{i = 0}^{L - 1} γ ( i ) {p}_{1} ( l - i ) \qquad ( 3 )$$

that computes the average over a finite window. Preferably Equation (3) gives different weights to the set of measurements p̅₁(l−i) under time varying channel conditions. Typically, the system sets the values so that γ(i) sums to one. The simplest case predetermines the window size and uses γ(i)=1/L. Such a simple case for finite window averaging is illustrated, for example, in U.S. patent application Ser. No. 10/894,913 to Despain, filed Jul. 19, 2004, entitled “Use of Adaptive Filter in CDMA Wireless Systems Employing Pilot Signals” which application is hereby incorporated by reference in its entirety.

A condition may arise in a communication system, including some important types defined by industry standards, where reference symbols are not available in every transmitted symbol. In the case of intermittent reference symbols, the averaging in Equation (1) preferably considers this absence and maintains either the same number L of symbols in the average or, if the receiver is in motion, reduces the value of L. It is generally desirable to determine the best trade-off between accuracy and tracking preferred for such a situation. When no training symbol is present at the input, the filter determination process of FIG. 4 preferably is paused and the received signal continues to be filtered with the last determined subspace filter.

L can be a function of speed in Equation (1). As the receiver's speed increases, the channel is likely to change significantly over a decreasing period of time, and L preferably is reduced. Therefore, it is desirable to determine a length L that adapts with the receiver's speed of motion or an analytical equivalent to such a length such as a functional or empirical relationship that determines length as a function of the receiver's relative velocity.

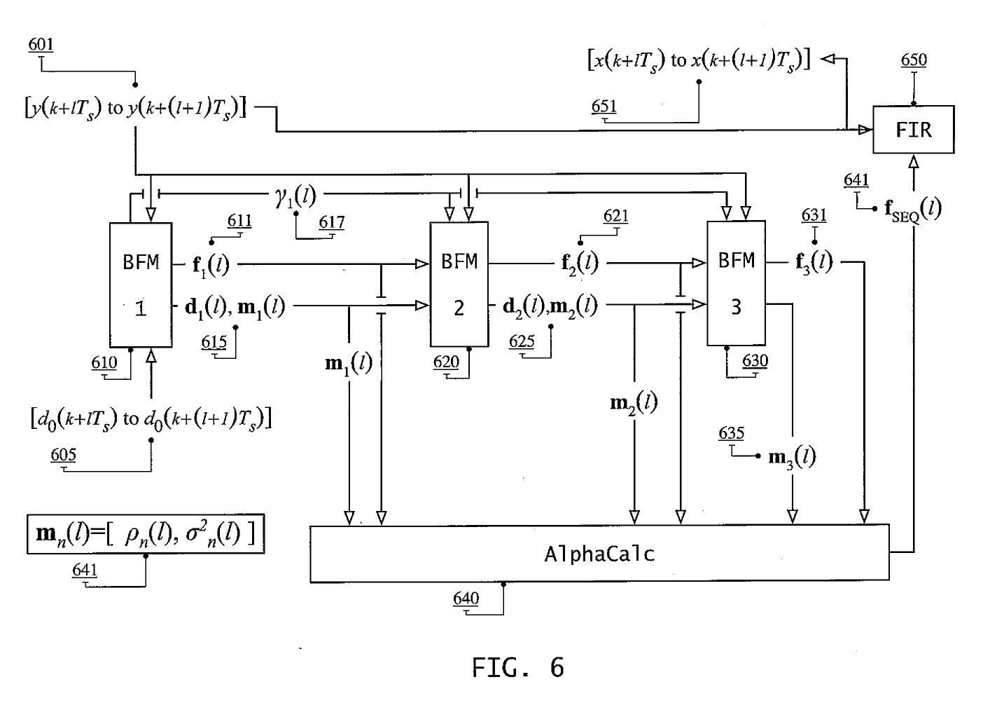

In some embodiments of the present invention, a preferred basis filter module uses a weighted average reformulation of Equation (1), as in Equation (3), for channel estimation,

$${\overline{p}}_{n} ( l ) = {\sum }_{i = 0}^{L - 1} {γ}_{n} ( i ) {p}_{n} ( l - i + b ) \qquad ( 4 )$$

where γₙ(i) are the weight coefficients. An implementation employing channel estimation as described by Equation (4) is illustrated in FIG. 6.

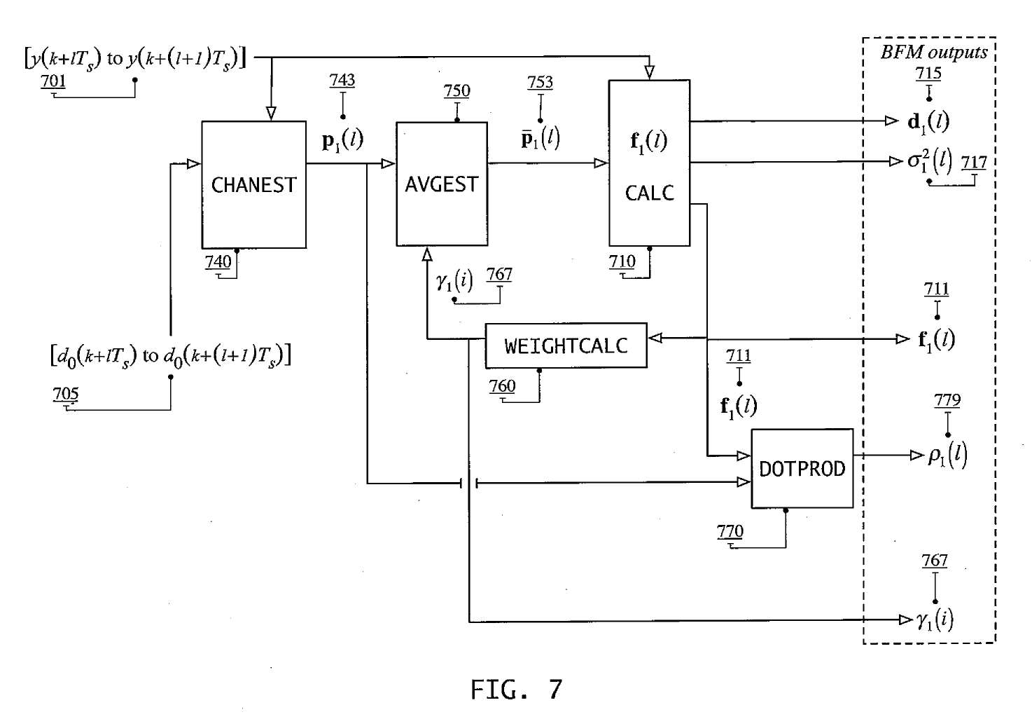

FIG. 6 shows a presently preferred subspace equalizer filter, which is a modification of the FIG. 4 subspace filter, and incorporates three basis filter modules. The FIG. 6 implementation improves mobile receiver performance, reduces overall computational complexity and reduces power consumption. The FIG. 6 implementation encompasses two metric computations: the use of the averaging method specified in Equation (4), and an additional metric ρ₁(l) computed inside of basis filter module 610. The metric ρ₁(l) is a measure of the similarity between the channel estimate and the first basis filter estimate. These modifications to determining the first basis filter module are shown in FIG. 7, which can be compared to the simple basis filter module of FIG. 5 that does not include the FIG. 7 enhancements to ameliorate the decrease in performance due to potential receiver mobility.

Like FIG. 4, FIG. 6 shows that the filtered data (e.g., 415) is provided to each basis filter module, for example from 610 to 620. In the FIG. 6 implementation, the filtered data is used by the first basis filter module and preferably is not used by any other computation module, as was the case with the subspace equalizer filter output calculation 440. This difference reduces the overall power consumption of the subspace equalizer computation, and simultaneously decreases computational complexity and data buffering requirements in any implementation. Instead, a preferred subspace equalizer filter determines and provides the metric 641, consisting of two scalars ρ(l), σ²(l) (complex and/or real), to a module AlphaCalc 640 that computes the scalar weighting function to combine the fₙ(l) into the best performing subspace equalizer. The elements in the metric vector 641 are computed as shown in FIG. 7. The WEIGHTCALC 760 module preferably computes the values of γₙ(i) required in the first (n=1) basis filter module 610, and preferably provides these values to all subsequent basis filter modules in preferred implementations. For the metric vector 641 and n=1, the module 770 generates the first term ρ₁(l). As with any nominal basis filter module, the module 710, or equivalently 510, determines the second term.

The first basis filter module in FIG. 4 preferably includes the modules CHANEST 540, AVGEST 550 and f₁-CALC 510. The illustration in FIG. 7 shows the WEIGHTCALC module 760 coupled to an AVGEST module 750 within the FIG. 7 basis filter module. This preferred implementation of a first basis filter module outputs the WEIGHTCALC weights γ₁(i) 767 for use by subsequent basis filter modules, if those subsequent modules do not include their own WEIGHTCALC module coupled to their respective AVGEST modules.

Equation (4) takes the present, future or past values (or combinations of them), of the symbol-based estimates pₙ(l−i+b) and averages them according to the previously calculated L values of the weights γₙ(i). It follows that 0≦b≦L−1 and it is preferable to select a value of b to center the present estimate p₁(l) in the summation of Equation (4). Therefore, to implement this weighted-average circuit as a causal system, the receiver preferably introduces b symbol delays (or more) from input to output.

Preferred subspace filters provide a way to calculate the values of γₙ(i). The calculation frequency for γₙ(i) may be selected to be slower than the symbol rate at which the channel estimate is done, or at which the index l dictates. This is an application-specific design issue.

Certain preferred embodiments of a filter and receiver preferably apply the condition that,

γₙ(i)=γ₁(i) (5)

That is, the various weights preferably are maintained the same for all basis filter modules in a subspace once the first basis filter module computes the various weights. Preferably, computing the weights is analytically given by the correlation

γ₁(i)=|f₁^{H}(l+b)f₁(l−i+b)| (6)

with the indexing sequence i=[0, 1, . . . , L−1] and the restriction that 0≦b≦L−1. Equation (6) (and its circuit, digital signal processor or other implementations) measures the similarity between channel estimates, and relates to the least-square estimate over several measurements. Symmetry about the index b>0 is preferred since there is a greater channel self-similarity to the nearest symbols in the past and future, and the system preferably takes advantage of that fact. Equalizers and channel shortening filters that rely on a channel estimate as one of its computational components can advantageously use this channel estimation strategy. This may not be the case for least mean square type adaptive equalizers but is generally the case for subspace filters.

Since the scalar in Equation (6) may be a complex-valued measure of similarity between the two filters, it is convenient to use the magnitude of Equation (6) to provide weight values for combining the basis filters. Other functions or characteristics of Equation (6) might alternately be used to provide the weights. For example, the maximum between the real and imaginary components of Equation (6) can be used as the weights, or the square of Equation (6) could provide the weights. To the extent the application or channel behavior dictate that a particular approach is more suited for a particular application, the system user preferably determines the best suited approach empirically and adopts it.

Particularly preferred embodiments of a filter or receiver automatically resolve the correspondence between receiver speed of motion (or relative velocity) and the value of L. Once the maximum value of L is determined, the filter preferably adjusts the L channel estimate measurements in accordance with the detected mobile speed within the finite measurement window by adjusting the values of γₙ(i). As the speed increases, the similarity generally decreases between pₙ(l+b) and pₙ(l+b+a) for a≠0. This dissimilarity will have the effect that values of γ₁(i) approach zero for delays of particular “a” or greater, depending on the Doppler rate. Although the finite window, with equal weighting terms, continues to have L-terms, the effective window length is shortened by the smaller values of γ₁(i). In some embodiments it may be advantageous to scale the values of γ₁(i) to provide no gain, that is, to set the sum of the weights equal to one.

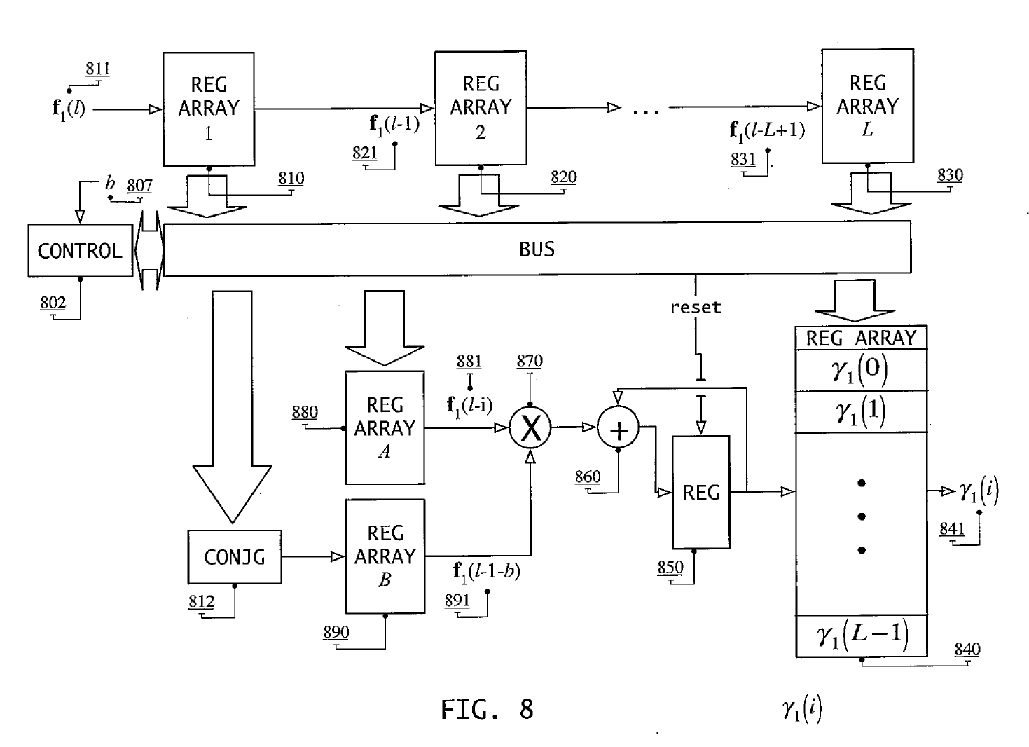

FIG. 8 shows the functionality and circuitry for determining the WEIGHTCALC 760 output γ₁(i) 767, given the current basis filter estimate 711. FIG. 8 shows that the current basis filter estimate 811 is queued into L register arrays, with each array represented by components 810, 820 and 830. The controller 802 in FIG. 8 copies the circuit basis filter fₙ(l) from its corresponding queue register array to a register array 890 that is one input to the multiplier 870. During this copy operation, the circuit 812 conjugates the values of fₙ(l). To generate the coefficient γ₁(i) the basis filter fₙ(l−i+b) is copied from its corresponding register array 810 to a register array 880 that serves as the second input to the multiplier 870. Register arrays 880 and 890 retain their values as the J multiplies, indexing in j, of f₁^{(f)}*(l) by f₁^{(f)}(l−i+b) are performed. After each multiply, indexing in j, the multiplier 870 output is added 860 to the previous value in the accumulator register 850. Note that the register array is reset with zero values when j=0. When j=J−1, and after the final accumulation is performed, the value in the accumulator register 850 is copied to the i^{th} location in the γ₁(i) register array 840. This process that generates γ₁(i) is commonly referred by those skilled in the art as a “dot product of two vectors.” This process is repeated for the next value of the index i. A module controller 802 preferably oversees operations such as copying, indexing the multiplier 870 registers and coordinating the bus to transfer values efficiently. Variations, including further refinements, of the circuits in FIG. 8 to optimize its operation given hardware and computational speed constraints while providing substantially the same output γ₁(i) 767 will be apparent to those of ordinary skill. Implementations of AVGEST 750 compute the average defined by Equation (4), given the weights γ₁(i) 767 in FIG. 7, which is easily designed by those of ordinary skill.

Most preferably, the weight values γₙ(i) are calculated in the first basis filter module, such as module 410 shown in FIG. 4, and the weight values are passed to the other basis filter modules in computing a subspace filter. This connectivity preferably implements the condition in Equation (5). A variation on this approach, albeit a variation with increased complexity, is to compute the averaging weights at each basis filter module. In this variation, all basis filter modules process the signals as shown in FIG. 7, and no values of γₙ(i) need be passed between the basis filter modules. If the weights from the first basis filter module are used in subsequent basis filter modules, then the overall subspace filter preferably is modified to pass the values from the first basis filter module to subsequent basis filter modules.

FIG. 8 shows a preferred hardware implementation that generates the values of γ₁(i). The fundamental operation the FIG. 8 circuit performs in determining the weights is a dot product, with the multiplier 870, which is defined as

$$\begin{matrix}{γ}_{1} ( i ) = \vert {f}_{1}^{H} ( l + b ) {f}_{1} ( l - i + b ) \vert \\ = \vert {\sum }_{j = 0}^{J - 1} {f}_{1}^{{( j )}^{*}} ( l + b ) {f}_{1}^{( j )} ( l - i + b ) \vert\end{matrix} \qquad ( 7 )$$

where * denotes conjugation and,

f₁^{T}(l)=[f₁⁽¹⁾(l)f₁⁽²⁾(l) . . . f₁^{(J-1)}(l)] (8)

Basis filter implementations offer a favorable decomposition related to the equalizer or channel shortening filter optimum solution. That is, the optimum filter solution fₒₚₜ is closely approximated by the subspace filter linear combination of the basis filters. That is,

fₒₚₜ≈f_{SF}=f₁+α₂f₂+α₃f₃+L+α_{D}f_{D}=f₁+F_{D}α (9)

where fₒₚₜ is determined through, most often, computationally intensive methods. The scalars αₙ are termed the basis filter coordinates (BFCs) and are calculated in or from basis filter coordinate modules (BFCMs). Various methods to design the basis filters fₙ are known. The previous discussion illustrated a method to adapt the basis filters in the presence of signal modulation or time-varying channels (or both) through averaging shorter time-span measurements. There are other known approaches to determine the coordinates that produce the closest approximation, in the least square sense, to fₒₚₜ. However, the averaging method illustrated in part by Equation (4) represents a particularly preferred method for determining the values of the basis filter coordinates.

One particular implementation effectively computes the basis filter coordinates when the basis filters are designed over a sufficiently long interval T+1 with no overlapping averaging between symbol estimates. That is, the channel estimate is computed over T+1 samples once, and all samples in that interval are filtered with one filter. This is equivalent to saying that p̅₁=p₁ and there is no indexing (l) over each symbol in the interval T+1, since only one averaging performed. This strategy preferably uses an iterative calculation that computes the basis filter coordinates as

$${α}_{n} = {( - \frac{1}{{w}_{1}} )}^{n - 1} {\prod }_{j = 1}^{n} {w}_{j} \qquad ( 10 )$$

where 1<n≦D and,

$${w}_{n} = \frac{\sqrt{{p}_{n}^{H} {p}_{n}}}{{ξ}_{n}} = \frac{{δ}_{n}}{{ξ}_{n}} \qquad ( 11 )$$

with,

ξₙ²=dₙdₙ^{H}−wₙ₊₁\sqrt{pₙ₊₁^{H}pₙ₊₁}=σₙ²−wₙ₊₁δₙ₊₁ (12)

The row vector dₙ includes the fₙ filter output samples that span T+1 block samples. To compute Equation (10), the iterations begin with the last basis filter module output d_{D} and continue with Equations (11) and (12) from n=D to 1. In practice, depending on the application, if the filter approximation f_{SF} is not explicitly calculated, then Equation (10) need not be computed and the system preferably uses the equivalence,

x=f_{SF}^{H}yₙ=w₁e₁=w₁(d₁−w₂e₂)

eₙ=dₙ−wₙ₊₁eₙ₊₁ (13)

instead. In Equation (13), the value of wₙ is specified to be the ratio of the two variables in the last term of Equation (11), which is a real-valued measure. Also in Equation (13), the row vector eₙ is determined instead of Equation (12), and Equation (12) is replaced with ξₙ²=eₙeₙ^{H}.

When the basis filters are estimated using Lanczos or Arnoldi methods and channel estimates averaged according to circuits like those shown in FIG. 5 and FIG. 7 and Equation (4), the determination of wₙ in Equation (11) preferably is altered to retain desired performance. This is described in detail in “Despain 2” (previously incorporated application Ser. No. 10/894,913).

Particular implementations of symbol modulation via OFDM or CDMA, which reduce the number of estimation samples from blocks of T+1 to Tₛ+1 samples, for time-varying channels require modifications to some computations or circuits. For example, averaging to improve the basis filter module estimates violates assumptions on which Equation (11) relies. Preferably, such implementations instead adopt a strategy like that described in Despain 2, application Ser. No. 10/894,913, previously incorporated by reference in its entirety. In such implementations, the value of δₙ is replaced with the computation of a dot product between a filter output dₙ₋₁ and the error signal eₙ, over the measure duration Tₛ+1, as the term in the numerator of Equation (11).

Either method for computing wₙ requires that the coordinates determinations for the basis filters be performed once all D basis filters are designed, prior to proceeding to so-called reverse stages that generate the values of wₙ and eₙ. The coordinates preferably are estimated in reverse order from D to 1, thus requiring D iterations to complete the determinations.

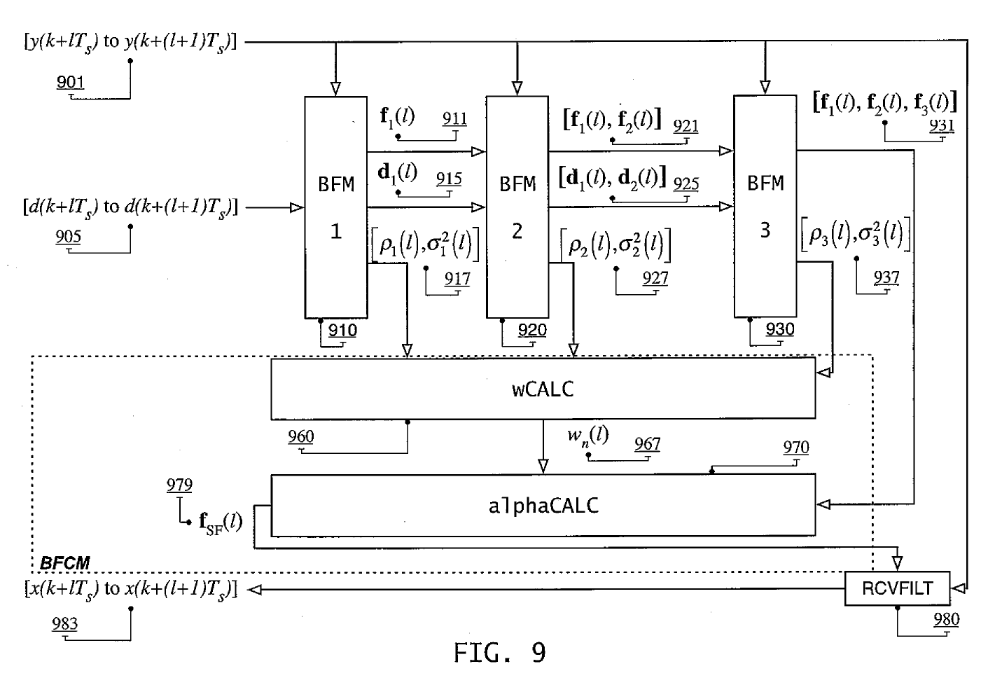

A preferred embodiment of the present invention for the coordinates calculations in a subspace filter takes a different approach, shown in FIG. 9. Although the circuit in FIG. 9 computes the wₙ's required in Equations (12) and (13), the circuit of FIG. 9 provides two additional advantages: (1) the wₙ's produce a superior subspace filter for use when channel estimate averaging is performed, and (2) the coordinates are determined with a significant reduction in multiplies and accumulates, and consequently, power consumption. Implementations of Equation (11) that use channel estimate averaging conditions may not achieve a high level of, or optimum, performance. According to Equation (13), high levels and even optimum performance can be achieved under channel estimate averaging conditions, using a higher computational complexity for each determination of wₙ. According to this high performance strategy, each filter sample output from each basis filter module preferably is transferred and buffered for the computations in Equation (13). A presently more preferred embodiment illustrated in FIG. 9 avoids such computational complexity by passing two variables, (e.g., [ρ₁(l),σ₁²(l)] 917), per symbol period from each basis filter module to the basis filter coordinate module. Note that these value-pairs 917, 927 and 937 imply that the wCALC module 960 computes its output 967 once per symbol, instead of working at a sampling rate clock, or faster, to compute its output as is typical in such known implementations as Despain 2, application Ser. No. 10/894,913, and U.S. Pat. No. 7,120,657 to Ricks and Goldstein. This preferred embodiment offers a reduction in multiply/add operations per symbol, and the clock rate at which multipliers and adders operate, which also provides a power consumption reduction critical to many mobile applications.

These scalars preferably are computed once per symbol, as are the basis filters. In particular, the dot product module 870 of FIG. 8 preferably generates ρ₁(l) in addition to determining other more typical aspects of generating basis filter modules. Prescribed basis filter modules compute the terms σₙ²(l) for certain basis filter generation strategies such as Lanczos and Arnoldi to be correction terms in determining the basis filters. The value σ₁²(l)=dₙ(l)dₙ^{H}(l) denotes the filtered signal output power at the n^{th} basis filter module over a symbol period.

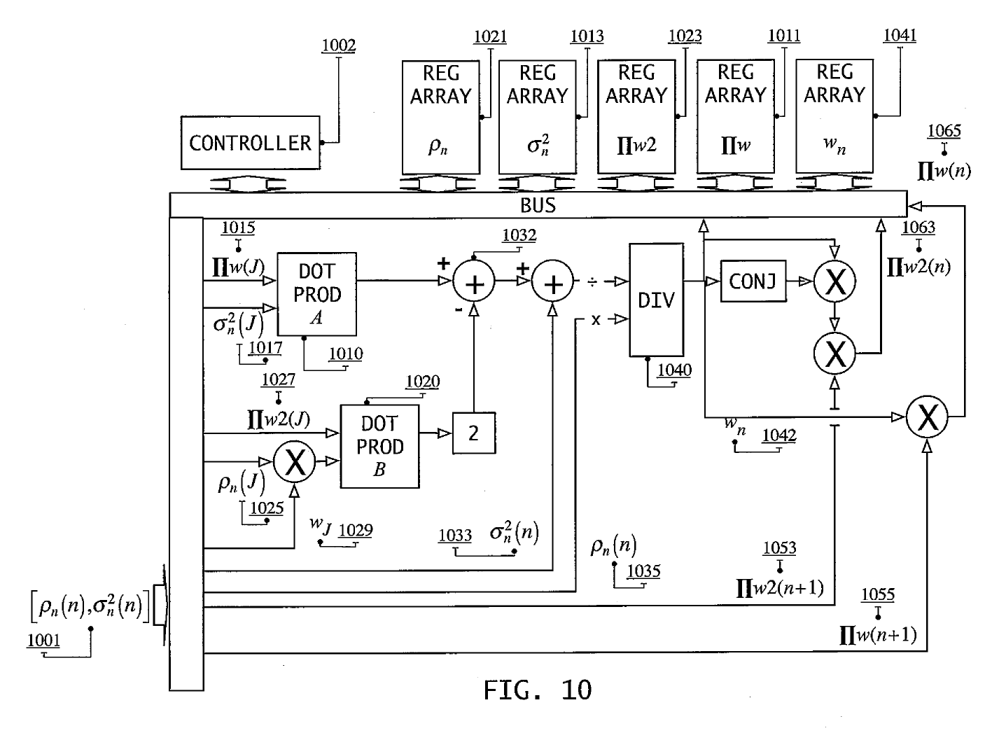

A preferred implementation that calculates the coordinates for the basis filters is shown in FIG. 10. FIG. 10 illustrates a hardware efficient implementation that calculates the coordinates αₙ starting with the D^{th} basis filter module and working backwards to n=1. Beginning with the outputs from the D^{th} basis filter module, the FIG. 10 circuit preferably calculates at any iteration n,

$$\begin{matrix}{w}_{n} ( l ) = \frac{{f}_{n}^{H} ( l ) {p}_{n} ( l )}{{ζ}_{n} ( l )} = \frac{{ρ}_{n} ( l )}{{ζ}_{n} ( l )} & ( 14 ) \\ where , & \\ \begin{matrix}{ζ}_{n} ( l ) = {σ}_{n}^{2} ( l ) + {\sum }_{J = n + 1}^{D} ( ( {\prod }_{K = n + 1}^{J} {w}_{K} ( l ) ) {σ}_{J}^{2} ( l ) ) - \\ 2 {\sum }_{J = n + 1}^{D} ( ( {\prod }_{K = n + 1}^{J - 1} {w}_{K}^{2} ( l ) ) {w}_{J} ( l ) {σ}_{J}^{2} ( l ) ) \\ ρ = {f}_{n}^{H} ( l ) {p}_{n} ( l )\end{matrix} & ( 15 )\end{matrix}$$

The complexity reduction realized in Equation (15) stems from the summations not exceeding D terms at an index n and the computations based on measurements calculated once per symbol, and all the variables being real and complex scalars (i.e., no vectors). Further complexity savings can be realized since the storage requirements, relative to those imposed by Equation (13), are generally minimized and the multipliers can operate nearly at the symbol rate as compared to the dot products on the filter outputs in Equation (13), that operate at the sample rate. Given that the first factor in the right side of the equivalence,

$${\prod }_{K = n + 1}^{J} {w}_{K} ( l ) = ( {\prod }_{K = n + 1}^{J - 1} {w}_{K} ( l ) ) {w}_{J} ( l ) \qquad ( 16 )$$

is determined in the previous iteration n−1, then only one additional multiplication for each indexing in the summation need be computed at the present iteration n. A circuit that takes advantage of previous calculations is shown in FIG. 10. For small values of D, it may be best to use D basis filter coordinate modules to perform the calculations in Equation (15), and pass registers that contain all past values to the next basis filter coordinate module. Alternatively, the design of a controller 1002 in FIG. 10 that iterates on the current state n, from D to 1, and selects the sequence of computations from components that perform dot products, adds, multiplies and divides may offer a more efficient hardware design.

The input pair [ρₙ(l),σₙ²(l)] 1001 preferably is stored in the corresponding register location, as by storing ρₙ(l) in register array 1021 and σₙ²(l) in the register array 1013. At the address n=D+1, the register arrays labeled Πw2 1023 and Πw 1011 are initialized to a value of 1. The last register array in the circuit is for wₙ 1023. The first computations at n=D preferably place the result into the first register of the wₙ register array 1023. Controller 1002 preferably iterates on n=n−1 until n=1, and also on index J=n+1 to D to place the proper values into the dot product circuit. Preferably controller 1002 initializes the values at the register locations n=D+1 for σₙ²(l) and ρₙ(l) to zero.

The first step to calculate wₙ is to compute the summations in Equation (15). Note that the index l is implicit. These dot product calculations are done with the dot product elements 1010 and 1020. The dot product 1010 gets the corresponding inputs by indexing the Πw 1011 and σ₁² registers on J to perform the J multiplies and adds. At n=D, the value of J=D+1 and the values for the registers are the initialization values stated above. For n<D, the dot products are calculated and the output of 1020 is multiplied by two 1030, before it is subtracted 1032 from the dot product 1010 output, which in turn is added to σ₁² 1034. This completes the calculation of Equation (15). The adder 1034 output is the dividend to ρ₁, which results in the value of wₙ according to Equation (14). The values at register n for Πw and Πw2 are then calculated and stored in the corresponding register arrays 1011 and 1023 respectively. The calculated value of wₙ. 1042 is stored at the n^{th} location of its register array 1041. The controller updates n=n−1, and if n>0, the FIG. 9 circuit performs the calculations again.

At the conclusion of computations in FIG. 10, the basis filter coordinates can be determined. Simply, the determination of the coordinates to satisfy Equation (8) is given by,

$${α}_{n} = {( - 1 )}^{n - 1} {\prod }_{j = 1}^{n} {w}_{j} , \qquad ( 17 )$$

and indexing from n=1 to D, the overall filter is determined according to,

f_{SF}=α₁f₁+α₂f₂+α₃f₃+L+α_{D}f_{D} (18)

The averaging method for cross-correlation estimates discussed above uses a finite number of basis filters, computed over a symbol period, to obtain an improved cross-correlation estimate. Other averaging methods with lower storage requirements might be used. One such formulation replaces Equation (4) with

p̅ₙ(l)=(1−λ) p̅ₙ(l−1)+λpₙ(l) (19)

where 0<λ<1, and the terms in Equation (19) are equivalent to those shown in FIG. 7. This update formulation is used in recursive least squares techniques, for instance. Another formulation adopts a steepest-descent formulation like that found in least mean squares strategies and given by

p̅ₙ(l)= p̅ₙ(l−1)+μpₙ(l) (20)

where μ=1. These two types of averaging have their benefits, such as simplicity, but can have fundamental channel-variation tracking problems. If Equations (19) or (20) are used in AVGEST 750, the basis filter coordinate module preferably has the configuration shown in FIG. 10, which provides particularly advantageous subspace filter performance. By contrast, the computation of wₙ in Equation (11) will result in significant greater estimation error of fₒₚₜ in Equation (10) when these averaging methods are used.

A consideration in mobile receiver applications for either a software or hardware equalizer implementation is circuit complexity and power consumption. The power consumption is proportional to the clock rate at which the multipliers/adders operate, as well as the total number of multipliers and adders. The preferred embodiment illustrated in FIG. 10 and the corresponding subspace filter of FIG. 9 incorporate a preferred embodiment that changes the coordinate computation from a sample clock rate dominated computation (e.g., as described in Despain 2, application Ser. No. 10/894,913), to one that is symbol clock rate dominated. That is, the inputs and outputs are provided to the wCALC 960 at the symbol rate. In many mobile applications, the number of samples per symbol can range from 64, for CDMA2000, up to 320 for WiMax. Typically, a high performance receiver will also oversample the input signal by at least a factor of two, thus further increasing the number of samples per symbol. It is also common for the equalizer length to be shorter than the number of samples in one symbol, thus, it is beneficial for the number of multiplies per symbol to be filter-driven, rather than data-driven.

The present invention has been described in terms of certain preferred embodiments. Those of ordinary skill in the art will appreciate that various modifications and alterations could be made to the specific preferred embodiments described here without varying from the teachings of the present invention. For example, the above-described circuits may be implemented as specialized circuitry, whether integrated or otherwise, within a digital signal processor (DSP), a general purpose microprocessor or combinations of these different implementation strategies. Consequently, the present invention is not intended to be limited to the specific preferred embodiments described here but instead the present invention is to be defined by the appended claims.

I claim:

1. A receiver comprising a subspace filter for filtering data, the receiver comprising:
a first basis filter, the first basis filter generating a plurality of channel estimates from received information including a current channel estimate for a current time interval, the current channel estimate determined as a weighted average of the plurality of channel estimates using a weighting function, the weighting function being a measure of similarity between channel estimates and varying as a function of relative receiver velocity so that the weighting function has a larger magnitude for channel estimates closer in time to the current time and has a smaller magnitude for channel estimates further in time from the current time,
wherein the first basis filter outputs a first basis filter estimate responsive to the current channel estimate and the received information; and
a second basis filter, the second basis filter receiving the first basis filter estimate and generating a second basis filter estimate responsive to the first basis filter estimate.

2. The receiver of claim 1, wherein the first and second basis filters are estimated over a time span of one symbol.

3. The receiver of claim 1, wherein at least one of the first and second basis filters is estimated over an integral number of symbol periods.

4. The receiver of claim 1, wherein the first basis filter further generates a first similarity measure between the first basis filter and a channel estimate, the first similarity measure used to generate a correction to the first basis filter estimate.

5. The receiver of claim 4, wherein the second basis filter further generates a second similarity measure between the second basis filter and a channel estimate, the second similarity measure used to generate a correction to the second basis filter estimate.

6. The receiver of claim 4, wherein the first similarity measure is generated in a process including a dot product.

7. The receiver of claim 4, wherein the first basis filter generates the first similarity measure using an averaged channel estimate and the first basis filter estimate.

8. The receiver of claim 4, wherein the weighted average is determined once per symbol.

9. A receiver comprising a subspace filter for filtering data, the receiver comprising:
a first basis filter, the first basis filter generating a plurality of channel estimates from received information including a current channel estimate for a current time interval, the current channel estimate determined as a weighted average of the plurality of channel estimates using a weighting function, the first basis filter outputting a first basis filter estimate responsive to the current channel estimate and the received information,
wherein the first basis filter generates a first similarity measure between the first basis filter and a channel estimate once per symbol, the first similarity measure used to generate a correction to the first basis filter estimate; and
a second basis filter, the second basis filter receiving the first basis filter estimate and generating a second basis filter estimate responsive to the first basis filter estimate.

10. The receiver of claim 9, wherein the first and second basis filters are estimated over a time span of one symbol.

11. The receiver of claim 9, wherein at least one of the first and second basis filters is estimated over an integral number of symbol periods.

12. The receiver of claim 9, wherein the second basis filter further generates a second similarity measure between the second basis filter and a channel estimate, the second similarity measure used to generate a correction to the second basis filter estimate.

13. The receiver of claim 9, wherein the first similarity measure is generated in a process including a dot product.

14. The receiver of claim 9, wherein the first basis filter generates the first similarity measure using an averaged channel estimate and the first basis filter estimate.

15. The receiver of claim 12, wherein the weighting function is a measure of similarity between channel estimates and varies as a function of relative receiver velocity so that the weighting function has a larger magnitude for channel estimates closer in time to the current time and has a smaller magnitude for channel estimates further in time from the current time.

16. A receiver comprising a subspace filter for filtering data, the receiver comprising:
a plurality of basis filters including a first basis filter and a second basis filter; and
a basis filter combination module that combines at least selected outputs of the plurality of basis filters to determine a subspace filter,
the first basis filter generating a plurality of channel estimates from received information including a current channel estimate for a current time interval, the current channel estimate determined as a weighted average of the plurality of channel estimates using a weighting function, the weighting function being a measure of similarity between channel estimates and varying as a function of relative receiver velocity so that the weighting function has a larger magnitude for channel estimates closer in time to the current time and has a smaller magnitude for channel estimates further in time from the current time,
wherein the first basis filter outputs a first basis filter estimate responsive to the current channel estimate and the received information, and the second basis filter receives the first basis filter estimate and generates a second basis filter estimate responsive to the first basis filter estimate,
wherein the first basis filter outputs the weighting function to at least the second basis filter.

17. The receiver of claim 16, wherein the basis filter combination module combines the at least selected outputs of the plurality of basis filters according to a measure corresponding to the weighting function.

18. The receiver of claim 16, wherein the basis filter combination module combines the at least selected outputs of the plurality of basis filters according to a measure determined from the weighting function.

19. The receiver of claim 16, wherein the basis filter combination module combines the at least selected outputs of the plurality of basis filters using the weighting function.

20. The receiver of claim 16, wherein the first basis filter generates a first similarity measure between the first basis filter and a channel estimate once per symbol and wherein the second basis filter generates a second similarity measure between the second basis filter measure and a channel estimate once per symbol, the first basis filter and the second basis filter outputting the first and second similarity measures respectively to the basis filter combination module.

21. The receiver of claim 20, wherein the first basis filter generates a first filtered signal output power and the second basis filter generates a second filtered signal output power, the first basis filter and the second basis filter outputting the first and second filtered signal output powers respectively to the basis filter combination module.

22. The receiver of claim 16, wherein the first basis filter generates a first filtered signal output power and the second basis filter generates a second filtered signal output power, the first basis filter and the second basis filter outputting the first and second filtered signal output powers respectively to the basis filter combination module.
